(19) United States
(12) Patent Application Publication
(10) Pub. No.: US 2005/0229061 A1
(43) Pub. Date: Oct. 13, 2005

(54) Method of efficiently compressing and decompressing test data using input reduction

(76) Inventors: Sung-Ho Kang, Seoul (KR); Sung-Hoon Chun, Seoul (KR); Yong-Joon Kim, Sungnam-Si (KR); Guen-Bae Kim, Seoul (KR)

Correspondence Address: Peter T. Kwon;G W i P S, Kangnam P. O. Box 2301, Seoul, 135-242, KR

(21) Appl. No.: 10/814,127

(22) Filed: Apr. 1, 2004

(51) Int. Cl. G01R 31/28; G06F 11/00

(52) U.S. Cl. 714/738

(57) ABSTRACT

A new test data compression method and decompression apparatus is invented for SoC (System-on-a-Chip) architecture. The method is based on analyzing the factors that influence test parameters: compression ratio and hardware overhead. To improve compression ratio, the proposed method is based on Modified Statistical Coding (MSC) and input reduction (IR) scheme, as well as a novel mapping and re-ordering algorithm proposed in a preprocessing step. Unlike previous approaches using the CSR architecture, the inventive method is to compress original test data, but not T_{diff}, and decompress the compressed test data without the CSR architecture. Therefore, the proposed method leads to better compression ratio with lower hardware overhead than previous works. An experimental comparison on ISCAS '89 benchmark circuits validates the proposed method.

### BACKGROUND OF THE INVENTION

1. Field of the Invention

The present invention relates to a new test data compression method and, more particularly, to a method of compressing and decompressing test data using an input reduction (IR) scheme and an MSCIR compression code in order to improve compression ratio.

2. Related Prior Art

As the complexity of a chip increases, an accurate test for the chip becomes more important. Furthermore, with the introduction of the system-on-chip (SoC) architecture, an increase in the quantity of test data used for testing the chip requires a new design for the test [Y.

Zorian, S. Dey, and M. J. Rodgers, “Test of Future System on Chips,” In Proceedings: International Conference on Computer Aided Design, pp. 392-400, 2001]. When automatic test equipment (ATE) is used for a SoC test requiring a vast amount of test data, the existing ATE should be reconstructed or an expensive ATE is needed because of the limited number of available test channels and memory of the ATE. To overcome the limitations of the test channels (bandwidth?) and memory of the ATE, studies on various methods are currently in progress.

One of the methods is to use built-in self-test (BIST) as shown in the ITRS roadmap [The International Technology Roadmap for Semiconductors, 1999 Edition, ITRS]. However, cores embedded in a SoC must be designed to be BIST-ready in order to use the BIST. In addition, the operation of the cores are affected by the BIST so that they must be designed in consideration of the effect of the BIST. Moreover, the embedded cores are difficult to correct, in general. Thus, the method of using the BIST is not an appropriate solution.

Another approach is to compress test data. This approach can be easily used for SoC design because it does not affect the operation of the chip when the chip is normally operated. Furthermore, this method is more efficient than the method of using the BIST because it compresses test data to use the compressed test data as a test input and decompresses the compressed data to the original test data using an internal decoder onboard the tested chip or a decoder provided by the ATE in order to test the SoC in the ATE.

Efforts to reduce test data size have been made in various ways. I. Hamzaoglu and J. H. Patel, et al. have proposed a method that reduces the number of test vectors to decrease the quantity of the entire test data [I. Hamzaoglu and J. H. Patel, “Test set compaction algorithms for combinational circuits,” In Proceedings: International Conference on Computer Aided Design, pp. 283-289, 1998; I. Pormeranz, L. Reddy, and S. Reddy, “Compactest: A method to generate compact test set for combinational circuits,” IEEE Transactions on Computer Aided Design, Vol. 12, pp. 1040-1049, 1993], and M. Ishida, D. A. Ha and T. Yamaguchi have proposed a technique that reduces the quantity of test data delivered to the ATE [M. Ishida, D. S. Ha, and T. Yamaguchi, “Compact: A hybrid method for compressing test data,” In Proceedings IEEE VLSI Test Symposium, pp. 62-69, 1998]. In addition, A. Chandra and K. Chakrabarty et al. have proposed a method of embedding a decoder in a chip [A. Chandra and K. Chakrabarty, “Frequency-Directed Run-Length (FDR) Codes with Application to System on a Chip Test Data Compression,” In Proceedings: IEEE VLSI Test Symposium, pp.114-121, 2001; A. Chandra and K. Chakrabarty, “System-on-a-Chip Test Data Compression and Decompression Architectures Based on Golomb Codes,” IEEE Transactions on Computer Aided Design, Vol. 20, pp. 113-120, 2001; A. El-Maleh, S. al Zahir, and E. Khan, “A Geometric Primitives Based Compression Scheme for Testing System-on-Chip,” In Proceedings for IEEE VLSI Test Symposium, pp. 114-121, 2001; V. Iyengar, K. Chakrabarty and B. Murray, “Deterministic Built In Pattern Generation for Sequential Circuits,” Journal of Electronics Testing: Theory and Applications, Vol. 15, pp. 97-114, 1999; A. Jas, J. Ghosh-Dastidar, and N. A. Touba, “Scan Vector Compression/Decompression Using Statistical Coding,” In Proceedings: IEEE VLSI Test Symposium, pp. 114-121, 1999; A. Jas and N. Touba, “Test Vector Decompression Via Cyclical Scan Chains and Its Application to Testing Core Based Designs,” In Proceedings: IEEE International Test Conference, pp. 458-464, 1998; A. Jas and N. Touba, “Using Embedded Processor for Efficient Deterministic Testing of System-on-Chip,” In Proceedings: International Conference on Computer Design, pp. 418-423, 1999; and P. Y. Gonciari, B. M. Al-Hashimi, and N. Nicolici, “Improving Compression Ratio, Area Overhead, and Test Application Time for System-on-a-Chip Test Data Compression/Decompression,” In Proceedings: Design, Automation and Test in Europe Conference and Exhibition, 2002].

A test data compression algorithm must not allow loss of information and requires a simple decoder for decompressing compressed test data to original test data. While the condition in which loss of information is not allowed is easily satisfied using a conventional compression algorithm without having loss of information (for example, Huffman coding, Lempel-Ziv compression algorithm and so on), the requirement for a simple decoder should be cautiously considered when the compression algorithm is developed. Iyengar has proposed a test data compression method for a sequential circuit using statistical coding. However, this approach can be used only for a circuit having a small number of main inputs.

To solve this problem, A. Jas, J. Chosh-Dastidar and N. A. Touba have proposed a new technique that divides test data into blocks of a predetermined length and codes the blocks [A. Jas, J. Ghosh-Dastidar, and N. A. Touba, “Scan Vector Compression/Decompression Using Statistical Coding,” In Proceedings: IEEE VLSI Test Symposium, pp. 114-121, 1999]. This method proposes a Huffman code having a modified form. Although this technique provides simple decoding, the configuration of a decoder becomes complicated as the block size increases, resulting in an increase in the entire hardware overhead.

A compression technique using a run-length code [A. Jas and N. Touba, “Test Vector Decompression Via Cyclical Scan Chains and Its Application to Testing Core Based Designs,” In Proceedings: IEEE International Test Conference, pp. 458-464, 1998] is based on the fact that test patterns affecting an actual test do not have many different bits. This compression technique converts an original test set T_{D} to a test set T_{diff} by calculating the similarity of test patterns of the test set. To convert the test set T_{diff} to the original test set again, a scan chain scheme such as a cyclic scan register (CSR) must be provided inside a chip. In this case, the additional CSR scan chain scheme as long as the length of a scan chain to which test data is input is needed in addition to hardware for decoding the compression algorithm, resulting in high hardware overhead.

A. Chandra and K. Chakrabarty have proposed a method of compressing the test set T_{diff} using FDR code and Golomb code at a very high compression ratio [“Frequency-Directed Run-Length (FDR) Codes with Application to System on a Chip Test Data Compression,” In Proceedings: IEEE VLSI Test Symposium, pp. 114-121, 2001; and “System-on-a-Chip Test Data Compression and Decompression Architectures Based on Golomb Codes,” IEEE Transactions on Computer Aided Design, Vol. 20, pp. 113-120, 2001]. While the Golomb code is a compression code depending on a run length, the FDR code is made in consideration of a run length and frequency. Thus, the FDR code has a higher compression ratio than the Golomb code.

P. Y. Gonciari, B. M. Al-Hashimi, and N. Nicolici have proposed VIHC code using the test set T_{diff} [“Improving Compression Ratio, Area Overhead, and Test Application Time for System-on-a-Chip Test Data Compression/Decompression,” In Proceedings: Design, Automation and Test in Europe Conference and Exhibition, pp., 2002]. The VIHC code shows a compression ratio similar to or higher than those of the Golomb code and FDR code and it has lower hardware overhead. However, the compression method using the test set T_{diff} should consider hardware in addition to a decoder because it uses the CSR scan architecture.

In the meantime, C. A. Chen and S. K. Gupta have proposed an input reduction (IR) scheme for reducing the number of test sets [“Efficient BIST TPG Design and Test Set Compaction via Input Reduction,” IEEE Transactions on Computer Aided Design of Integrated Circuit and Systems, Vol. 17, pp., 1998].

The IR scheme takes advantage of compatibility and inverse compatibility. When different inputs have the same input value all the time, these inputs are compatible. The compatible inputs can be combined into one input. When different inputs have input values opposite to each other all the time, these inputs are inversely compatible. The inversely compatible inputs can be combined into one input using only one inverter. A technique of finding compatible inputs and inversely compatible inputs to reduce the number of test inputs of the original test data T_{D} to that of the test data T_{IR} is called the IR scheme.

The compatibility and inverse compatibility are explained using the c17 circuit that is the smallest circuit among ISCAS '85 benchmark circuits, shown in FIG. 1A. As shown in FIG. 1A, the c17 circuit has five inputs I₁ through I₅ and two outputs O₁ and O₂. In the c17 circuit, the size of the largest cone is 4. A test set of the c17 circuit, generated using the Atlanta ATPG tool proposed by H. K. Lee and D. S. Ha [H. K. Lee and D. S. Ha, “On the Generation of Test Patterns for Combinational Circuits,⇄ Tech. report no. 12_{—}93, Department of Electrical Engineering, Virginia Tech], is shown in FIG. 1B. Referring to FIG. 1B, the inputs I₁, I₄ and I₅ have the same value except for certain unspecified bits denoted by X, which can be either 0 or 1. The X bits of a certain input can be replaced with appropriate values to make them compatible with other inputs, if the corresponding values do not conflict with each other. Thus, the first, fourth and fifth rows of FIG. 1B can be considered to have the same input values. These inputs I₁, I₄ and I₅ having the same value are called compatible inputs. When the number of inputs is reduced in this way, the quantity of test data can be decreased as shown in FIG. 1C. Referring to FIG. 1C, the ‘X’ values of the input I₁ are replaced with the corresponding values of the inputs I₄ and I₅. By doing so, the quantity of the test data can be reduced by 20 bits. Inputs having values opposite to each other are called inversely compatible inputs. The IR scheme finds compatible inputs and inversely compatible inputs to reduce the quantity of test data. When the IR scheme is applied to the test data, the c17 circuit can be modified as shown in FIG. 2 such that only three test data items are input to the circuit.

When it is assumed that v(i, k) is the kith test pattern value, k(0≦k≦L−1), of an input i(0≦i≦N−1) of test data T having N inputs and L test patterns, compatibility of the inputs can be defined as follows.

[Definition 1]

Compatibility: Two inputs i and j of the test data T are compatible when 0≦k≦L−1 and v(i,k)=v(j,k) The inputs i and j must not conflict with given values of other different inputs that are compatible or inversely compatible when v(i,k)=X or v(j,k)=X

When \overline{v}(i,k) is defined as an opposite value of v(i,k), inverse compatibility can be defined as follows.

[Definition 2]

Inverse compatibility: The two inputs i and j of the test data T are inversely compatible when 0≦k≦L−1 and v(i,k)=\overline{v}(i,k). The inputs i and j must not conflict with given values of other different inputs that are compatible or inversely compatible when v(i,k)=X or v(j,k) X Test data compression can be easily carried out without loss of information of the test data through an IR scheme that finds compatible inputs and inversely compatible inputs using the above definitions.

As shown in FIG. 3, for the compatible input, only the length of an input line for test is increased. For the inversely compatible input, the length of a corresponding input line is increased and only a single NOT gate is added. Accordingly, the quantity of test data can be simply reduced without increasing hardware overhead.

If at least two inputs are compatible or inversely compatible, the inputs are compressed into one input through a simple circuit including a NOT gate and a fanout.

### SUMMARY OF THE INVENTION

Therefore, the present invention has been made in view of the above problems, and it is an object of the present invention to provide a test data compression method using a modified statistical code using input reduction.

Another object of the present invention is to provide a test data decompression apparatus that decompresses test data compressed using the modified statistical code, inputs the decompressed test data to a scan chain of the tested device and controls signals of an ATE and FSM.

To accomplish the above objects, according to one aspect of the present invention, there is provided a test data compression method comprising a step (a) of finding compatible inputs and inversely compatible inputs using given test data T_{D}; a step (b) of generating a compression code based on a statistical coding; a step (c) of replacing unspecified bits (‘X’ values) of the test data with specific values chosen to maximize compression of the test data; a step (d) of re-ordering a sequence of patterns of the test data to generate as many instances as possible of the bit pattern to be compressed based on the size of the blocks; and a step (e) of compressing the blocks using the compression code, in which the compression code is generated in such a manner that only one recurring 4-bit pattern that has the highest frequency of appearance is compressed into a 1-bit compression code and the other bits are grouped into blocks consisting of a 2-bit codeword, the 2-bit codeword blocks having the original values of the bits.

To accomplish the above objects, according to another aspect of the present invention, there is also provided a test data decompression apparatus including a controller that decompresses test data compressed by the test data compression method as claimed in claims 1, 2 and 3, inputs the decompressed test data to a scan chain of the tested device, and controls signals transmitted between an ATE and an FSM. The test data decompression apparatus comprises an FSM decoder that includes inputs, one of which is a test clock input and the other one of which is an input to which the compressed test data is transmitted from a channel of a tester, and outputs, one of which is a data output port through which original data obtained by decompressing the compressed data is transmitted and the other one of which is an output port through which control signals are output; and a serializer that inputs the decompressed test data to the scan chain in synchronization with an FSM clock of the FSM decoder and a chip test clock.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1A shows the c17 ISCAS '85 benchmark circuit.

FIG. 1B shows test data of the c17 benchmark circuit.

FIG. 1C shows test data obtained by reducing the number of compatible inputs of the c17 benchmark circuit.

FIG. 2 shows a circuit configuration for a test to which the IR scheme is applied.

FIG. 3 shows a structure of compatible and inversely compatible inputs.

FIG. 4 shows a decompression structure in a general SoC.

FIG. 5A shows the first decision pattern of the s13207 benchmark circuit when full scan is assumed.

FIG. 5B shows an example of Huffman codes and modified statistical codes based on the pattern of FIG. 5A.

FIG. 6 shows a procedure of re-ordering a test pattern sequence.

FIG. 7 shows a state change diagram of an FSM decoder for the modified statistical code.

FIG. 8 shows a controller for an FSM decoder of a compression method according to the present invention.

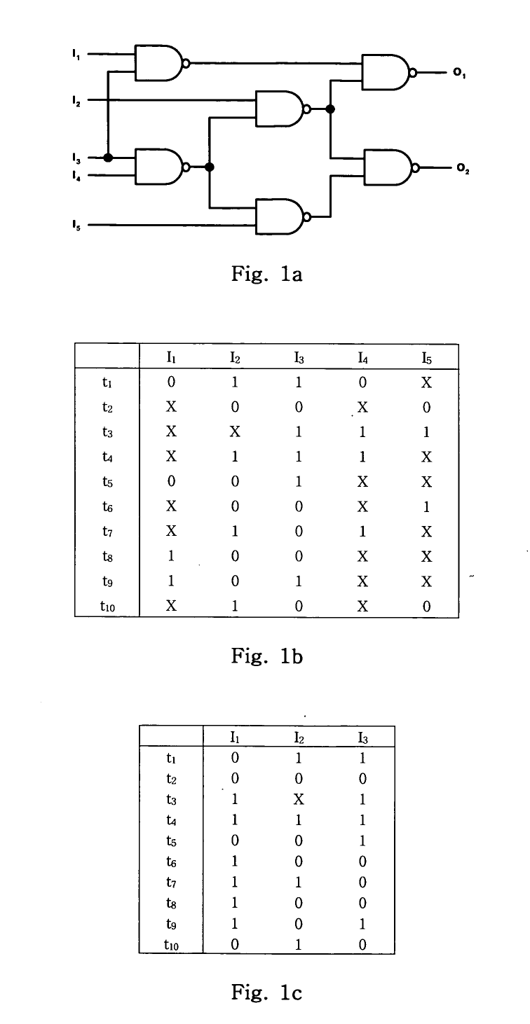

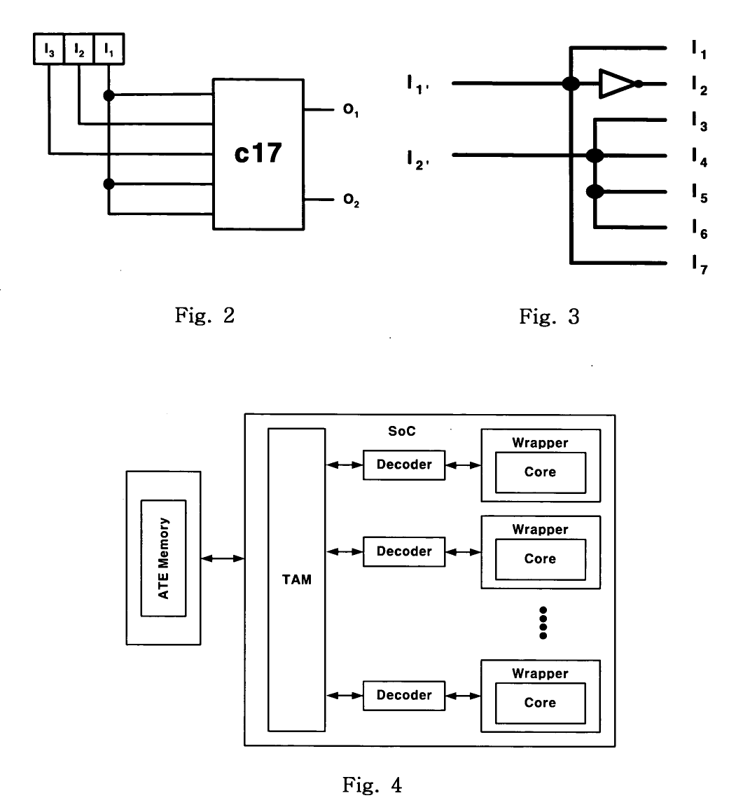

### DETAILED DESCRIPTION OF THE PREFERRED EMBODIMENT

A detailed description of the preferred embodiment of the present invention will now be given with reference to the attached drawings.

1. Modification of the IR Scheme

The present invention modifies the conventional IR scheme and proposes a new IR scheme for improving compression ratio. The new IR scheme finds inputs that can use identical test inputs without diminishing the failure detection ratio of a conventional test pattern. Distinguished from the conventional IR scheme proposed by C. A. Chen and S. K. Gupta [“Efficient BIST TPG Design and Test Set Compaction via Input Reduction,” IEEE Transactions on Computer Aided Design of Integrated Circuit and Systems, Vol. 17, pp., 1998], the IR scheme of the present invention requires finding compatible inputs and inversely compatible inputs using given test data T_{D} because the IR scheme of the invention has no regard for ATPG for BIST. Thus, the IR scheme of the present invention needs a new IR algorithm.

input reduction ( )
T_{D}: test set
N: the number of inputs
L: the length of the test sequence
C: the set to check whether target
{
int i;
int j;
Int k; //sequence k(0≦k≦L−1)
int check;

In the above-exemplified algorithm, first, an input check set C is prepared and the value corresponding to each input N,Cᵢ(0≦i≦N−1), is initialized to UNIQUE. Here, UNIQUE means that an input i is not compatible or inversely compatible. Compatibility between an input v(i,k) and a comparison input v(j,k) is detected over the entire test sequence k(0≦k≦L−1) of the given test data T_{D} using a function is compatible based on the concepts of the above-described Definitions 1 and 2. If the input v(i,k) or v(j,k) has a value ‘X’ (don't care), it is confirmed whether there are values that conflict with previous other compatible inputs or inversely compatible inputs using a function conflict check within the function is compatible.

2. Compression Method According to the Present Invention

Recently proposed compression techniques concern codes for effectively compressing test data T_{diff} [A. Chandra and K. Chakrabarty, “Frequency-Directed Run-Length(FDR) Codes with Application to System on a Chip Test Data Compression,” In Proceedings: IEEE VLSI Test Symposium, pp. 114-121, 2001; A. Chandra and K. Chakrabarty, “System-on-a-Chip Test Data Compression and Decompression Architectures Based on Golomb Codes,” IEEE Transactions on Computer Aided Design, Vol. 20, pp. 113-120, 2001; and A. Jas and N. Touba, “Using Embedded Processor for Efficient Deterministic Testing of System-on-Chip,” In Proceedings: International Conference on Computer Design, pp. 418-423, 1999]. Thus, compression ratio is deteriorated if the test data T_{diff} is not used. However, when the test data T_{diff} is used, the CSR architecture is necessarily used, so hardware overhead is increased. A conventional decompression structure for decompressing compressed test data in a SoC is shown in FIG. 4. As shown in FIG. 4, the decompression structure requires separate decoders that respectively decode test data compressed in embedded cores of the SoC to the original test data. Accordingly, the conventional compression techniques using T_{diff} need an additional CSR architecture including a flip-flop, at least one test input and a single XOR gate in addition to the decoders that decode compression codes. This remarkably increases hardware overhead of the SoC. Furthermore, since both the FSM of the decoder and a circuit for controlling it have large sizes, it is ineffective to embed the decoder in the SoC. Accordingly, a more efficient compression method is required. To solve the problems of the conventional compression techniques, the present invention proposes a new compression method that efficiently compresses test data without using the T_{diff} data set and has a simple decoder structure.

2.1 Compression Code According to the Present Invention

Conventional compression coding techniques without using the T_{diff} data set [I.

Pormeranz, L. Reddy, and S. Reddy, “Compactest: A method to generate compact test set for combinational circuits,” IEEE Transactions on Computer Aided Design, Vol. 12, pp. 1040-1049, 1993; A. Jas, J. Ghosh-Dastidar, and N. A. Touba, “Scan Vector Compression/Decompression Using Statistical Coding,” In Proceedings: IEEE VLSI Test Symposium, pp. 114-121, 1999] replaced lots of ‘X’ values in the test patterns with appropriate specific values to increase the frequency of appearance of a block to be compressed. However, these techniques increase compression ratio when the frequencies of appearance of blocks having a codeword with an appropriate size are similar, because the techniques are based on the Huffman code or statistical code. Moreover, as the number of blocks to be compressed increases, hardware overhead also increases remarkably.

To solve the problems of the conventional methods, the present invention proposes the modified statistical code using the IR scheme (MSCIR). The compression coding of the present invention compresses only one block consisting of a 4-bit codeword that has the highest frequency of appearance into a 1-bit compressed code and groups the remaining bits into blocks, each of which has a 2-bit codeword. The 2-bit codeword blocks have original values. Because decision test patterns have lots of ‘X’ values in general, it is easy to increase the frequency of appearance of one particular 4-bit block by replacing the ‘X’ values with appropriate values.

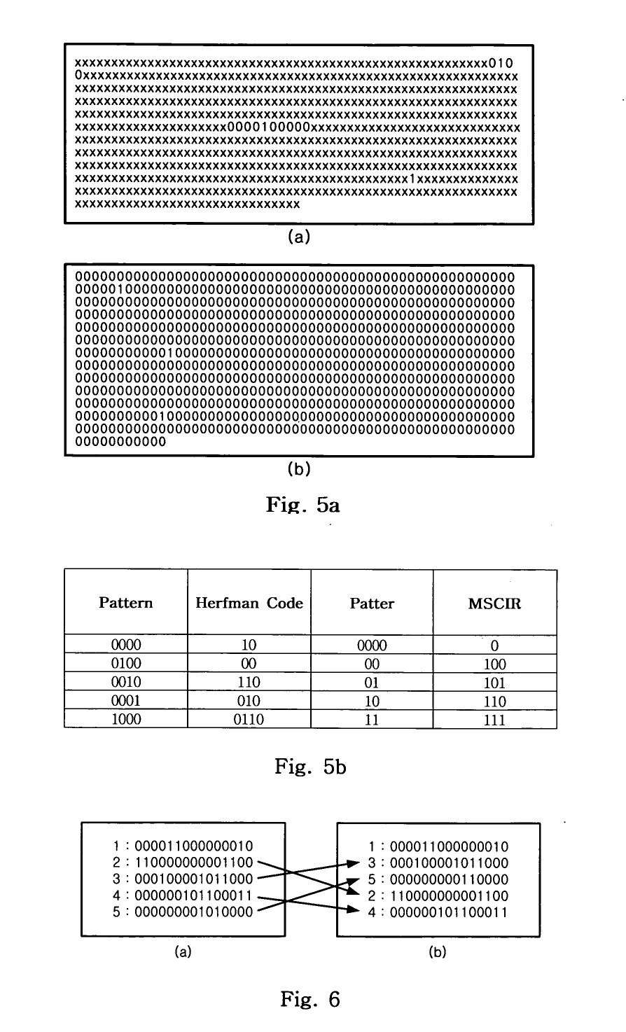

As an example, FIG. 5A(a) shows the first test pattern of the s13207 benchmark circuit before a compression code is applied. The s13207 benchmark circuit is one of the ISCAS 89 benchmark circuits in which a full scan structure is assumed. FIG. 5A(b) shows that ‘X’ values of the first test pattern are replaced with ‘0’s in order to increase the frequency of appearance of a block ‘0000’. It can be known from FIGS. 5A that it is easy to increase the frequency of appearance of a specific block to be compressed by replacing ‘X’ values with specific values while improving compression ratio.

The reason why bits that are not compressed are grouped into 2-bit blocks is explained now. Let it be assumed that there is a pattern ‘000010000010’, for example. In this case, if the pattern is divided into blocks each of which has a 4-bit codeword and the specific block to be compressed is ‘0000’, there is only one block that can be compressed. However, if bits that are not compressed are grouped into 2-bit blocks, the pattern has two ‘0000’ blocks. Therefore, 2 bits are allocated to each block that is not compressed in order to increase the frequency of appearance of a specific block to be compressed and improve compression ratio. As described above, the present invention uses the technique of grouping the bits that are not compressed into 2-bit blocks to increase the frequency of appearance of a specific block. FIG. 5B shows a comparison of the MSCIR generated on the basis of the pattern of FIG. 5A with the Huffman code.

2.2 Compression Algorithm

The compression algorithm for generating the modified statistical code according to the present invention is divided into three steps. The first step replaces ‘X’ values of test data with specific values for efficiently compressing the test data. The second step reorders a pattern sequence to generate as many instances as possible of the block to be compressed. The third step compresses the reordered test data using the new compression code.

When it is assumed that test data compressed using the IR scheme is T_{IR}, the test data T_{IF} still has lots of ‘X’ values. Thus, the ‘X’ values are replaced with appropriate values according to a compression code for efficiently compressing them. The compression algorithm of the invention replaces all the ‘X’ values with ‘0’s to allow patterns having many ‘0’s. Then, the pattern sequence of the test data having many ‘0’s is reordered such that blocks having consecutive ‘0’s appear more frequently. The first value and the last value of each pattern are stored and the length of each pattern is calculated. The pattern sequence is reordered such that the last value of each pattern becomes identical to the next pattern and many instances of the block to be compressed are generated. FIG. 6 shows an example of re-ordering a pattern sequence when one block has a 4-bit codeword.

One 4-bit block pattern having the highest frequency of appearance is selected from the reordered test data using the MSCIR and compressed. It is not difficult to increase the frequency of appearance of a specific block because test patterns have many ‘X’ values as described above.

2.3 Decompression Structure

To use the test data compressed using the aforementioned compression method for a test, it is required that an ATE includes hardware that decompresses the compressed test data or a SoC has the decompression hardware. It is much easier to embed the decompression hardware in the SoC than to include it in the ATE.

A general decompression structure embedded in the SoC includes a decoder and a controller that controls signals transmitted between the decoder and the ATE. As described above, the compression method of the present invention does not need the CSR architecture, reducing hardware overhead required for the decompression structure, unlike previous approaches [A. Chandra and K. Chakrabarty, “Frequency-Directed Run-Length(FDR) Codes with Application to System on a Chip Test Data Compression,” In Proceedings: IEEE VLSI Test Symposium, pp. 114-121, 2001; A. Chandra and K. Chakrabarty, “System-on-a-Chip Test Data Compression and Decompression Architectures Based on Golomb Codes,” IEEE Transactions on Computer Aided Design, Vol. 20, pp. 113-120, 2001; A. Jas, J. Ghosh-Dastidar, and N. A. Touba, “Scan Vector Compression/Decompression Using Statistical Coding,” In Proceedings: IEEE VLSI Test Symposium, pp. 114-121, 1999; A. Jas and N. Touba, “Using Embedded Processor for Efficient Deterministic Testing of System-on-Chip,” In Proceedings: International Conference on Computer Design, pp. 418-423, 1999]. In the decompression structure of the invention, it is assumed that the ATE can perform clock synchronization, as seen from the researches of D. Heidel, S. Dhong, P. Hofstee, M. Immediato, K. Nowka, J. Silaberman, and K. Stawiasz [“High-speed Serialiazing/Deserializing Design-for-Test Methods for Evaluating a 1-GHz Microprocessor,” In Proceedings: IEEE VLSI Test Symposium, pp. 234-238, 1998].

The decoder for decoding the MSCIR uses a simple FSM decoder. This decoder has two inputs, one of which is a tester clock input and the other an input to which compressed test data is transmitted from a channel of a tester. The FSM decoder has an output port through which original data obtained by decompressing the compressed data is transmitted and an output port through which three control signals are output. The three control signals include a signal “parallel load (Par.)”, a signal “serial load (Ser.)” and a signal “Wait”. These signals are sent to a serializer when the compressed data is decoded and they are required for buffering and synchronization with the ATE.

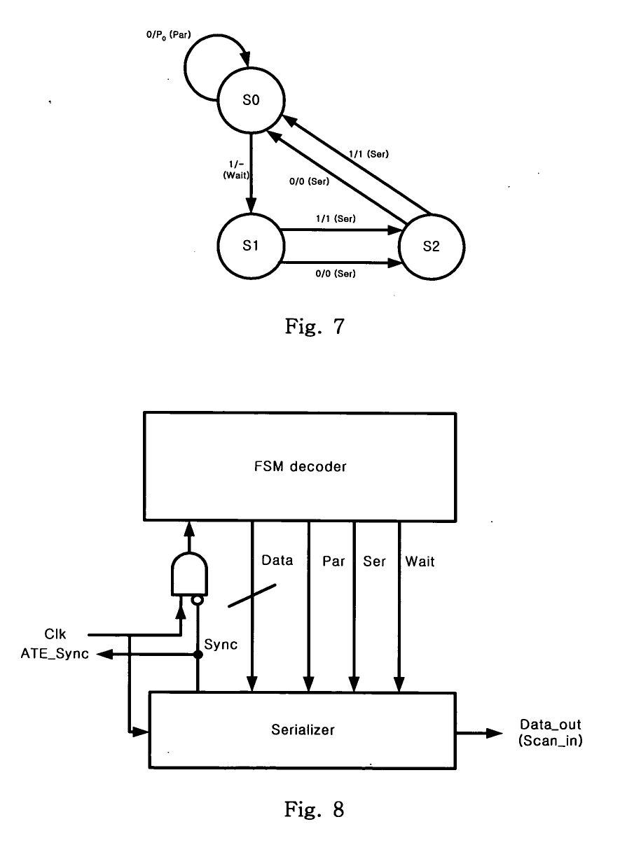

A state change diagram for the FSM decoder is shown in FIG. 7. Each compressed codeword has a bit that represents whether a corresponding pattern is compressed or not. In the compression code proposed by the present invention, when the first bit is ‘1’, it represents a pattern that is not encoded. If the first bit is ‘0’, it means an encoded pattern. Accordingly, when ‘1’ is input as the first bit of the codeword, which means a pattern that is not compressed, the decoder simply transmits subsequent bits and the control signal Ser to the serializer for two clock cycles. When ‘0’ is input as the first bit of the codeword, which indicates a compressed block, the decoder delivers P₀ corresponding to bits of the block and the control signal Par to the serializer in parallel.

A controller that inputs the test data decoded by the FSM decoder to a scan chain of a tested circuit and controls signals transmitted between the ATE and FSM decoder is shown in FIG. 8. The controller that executes the compression method of the invention includes the serializer that inputs the decoded test data to the scan chain in synchronization with a chip test clock Clk and a unit that synchronizes the chip test clock with a FSM clock. When a sync signal becomes ¢1” in the serializer, the FSM clock is stabilized so that the decoding operation of the decoder is stopped and the serializer transmits the test data to the scan chain. When the sync signal becomes “0”, the FSM decoder operates and, simultaneously, the serializer delivers the test data to the scan chain.

3. Experimental Results

Experiments using ISCAS '89 benchmark circuits were performed in order to estimate the performance of the compression method of the present invention. The experiments were executed on a Pentium 3 667 MHz Linux system using C. A test pattern for each circuit used test data generated using the ATPG tool called MINTEST for comparing the compression method of the invention with the conventional approaches. Furthermore, the experiments of the invention were based on the size of the block showing the best performance in each benchmark circuit from the experimental results of P. Y. Gonciari, B. M. Al-Hashimi, and N. Nicolici [“Improving Compression Ratio, Area Overhead, and Test Application Time for System-on-a-Chip Test Data Compression/Decompression,” In Proceedings: Design, Automation and Test in Europe Conference and Exhibition, pp. ???, 2002].

However, the block size of the compression method according to the present invention was fixed at 4 bits. In addition, while methods using SC code [A. Jas, J. Ghosh-Dastidar, and N. A. Touba, “Scan Vector Compression/Decompression Using Statistical Coding,” In Proceedings: IEEE VLSI Test Symposium, pp. 114-121, 1999], Golomb code [A. Chandra and K. Chakrabarty, “Frequency-Directed Run-Length(FDR) Codes with Application to System on a Chip Test Data Compression,” In Proceedings: IEEE VLSI Test Symposium, pp. 114-121, 2001], FDR code [A. Chandra and K. Chakrabarty, “System-on-a-Chip Test Data Compression and Decompression Architectures Based on Golomb Codes,” IEEE Transactions on Computer Aided Design, Vol. 20, pp. 113-120, 2001], VIHC code [P. Y. Gonciari, B. M. Al-Hashimi, and N. Nicolici, “Improving Compression Ratio, Area Overhead, and Test Application Time for System-a-Chip Test Data Compression/Decompression,” In Proceedings: Design, Automation and Test in Europe Conference and Exhibition, pp. ???, 2002] generated and used the test data T_{diff} to obtain the maximum compression ratio, the compression method using the MSCIR according to the present invention used the original test data T_{D}, not the test data T_{diff}. The result in Table 1 below.

TABLE 1

| Circuit | Block Size | SC | Golomb | FDR | VIHC | MSCIR |
|---|---|---|---|---|---|---|
| s5378 | 4 | 34.79 | 40.70 | 48.19 | 51.52 | 79.64 |
| s9234 | 4 | 35.52 | 43.34 | 44.88 | 54.84 | 76.14 |
| s13207 | 16 | 77.73 | 74.78 | 78.67 | 83.21 | 86.20 |
| s15850 | 4 | 40.16 | 47.11 | 52.87 | 60.68 | 85.44 |
| s38417 | 4 | 37.11 | 44.12 | 54.43 | 54.51 | 92.38 |
| s38584 | 4 | 37.72 | 47.71 | 52.85 | 56.97 | 93.53 |

As can be seen from FIG. 5B, the compression method of the invention provides compression ratios much higher than those of the conventional compression methods for all circuits. The reason for this is that, unlike the conventional compression methods, the compression method of the invention reduces the number of test inputs using the IR scheme so as to copnsiderably decrease the quantity of the test data.

Table 2 shows a comparison of hardware overheads for decompression structures of the conventional compression techniques with that of the decompression structure for the MSCIR code according to the present invention. The hardware overheads were calculated using the Design compiler of Synopsys. For objective comparison, all the hardware overheads were calculated using 1 si 10 k library that is the basic library of Synopsys. The block size was fixed to 4 bits in the MSCIR of the present invention.

TABLE 2

| Block Size | SC | Golomb | FDR | VIHC | MSCIR |
|---|---|---|---|---|---|
| 4 | 349 | 125 | 320 | 136 | 120 |
| 8 | 587 | 227 | | 201 | |
| 16 | 900 | 307 | | 296 | |

As shown in Table 2, the decompression structure for the MSCIR according to the present invention has the smallest hardware overhead.

The conventional compression methods using Golomb, FDR and VIHC codes require the CSR architecture in order to improve compression ratio. However, hardware overhead required for the CSR architecture is also very large. For example, the s35932 benchmark circuit, one of the larger ISCAS '89 benchmark circuits, needs a total of 1763 inputs including a main input and a scan input. When it is assumed that a single scan chain is constructed of the 1763 inputs, 1763 flip-flops and one XOR gate are needed in order to produce the CSR architecture. If the inputs are divided into a plurality of scan chains, hardware overhead will be reduced. However, the hardware overhead is still large, resulting in a large circuit. As the number of circuit inputs including the scan input increases, the hardware overhead also increases. In the case where the method of using an unused scan chain instead of the CSR architecture, proposed by A. Jas and N. Touba, is employed in order to solve the above-described problems, the length of the scan chain must be identical to the number of scan chain inputs to be decompressed. It is very difficult to apply the restriction on the length of the scan chain to all circuits. Furthermore, this technique requires an additional control circuit that converts the unused scan chain to the CSR architecture and controls it so that overhead is inevitably increased. Moreover, the decompression structure is provided for each of the cores to be tested in the SoC. Accordingly, hardware overhead of the decompression architecture increases as the number of cores in the SoC increases. Therefore, the compression method of the present invention is the most efficient compression technique having high compression ratio and very small hardware overhead.

As described above, the efficient test data compression method using the IR scheme according to the present invention uses test data generated by ATPG, not the test data T_{diff} using the CSR architecture, and does not have additional hardware overhead. The compression method of the invention can reduce the number of test inputs required for a test using the IR scheme instead of the test data T_{diff} so as to decrease the quantity of the test data without losing any of the test data. The compression method of the invention compresses the reduced test data using the MSCIR. The MSCIR code is easily decoded so that the decompression architecture for decoding the MSCIR is simple. Accordingly, the decompression architecture has smaller hardware overhead than the conventional compression methods. Moreover, the compression method according to the present invention can improve compression ratio while reducing hardware overhead.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

1. A test data compression method comprising steps of:
(a) finding compatible inputs and inversely compatible inputs using given test data T_{D};
(b) generating a compression code based on a statistical coding;
(c) replacing unspecified bits (‘X’ values) of the test data with specific values chosen to maximize compression of the test data;
(d) re-ordering a sequence of patterns of the test data to generate as many instances as possible of the bit pattern to be compressed based on the size of the blocks; and
(e) compressing the blocks using the compression code,
wherein the compression code is generated in such a manner that only one recurring 4-bit pattern that has the highest frequency of appearance is compressed into a 1-bit compression code and the other bits are grouped into blocks consisting of a 2-bit codeword, the 2-bit codeword blocks having the original values of the bits.

2. The test data compression method as claimed in claim 1, wherein the step (a) comprises the steps of:
preparing an input check set C and initializing Cᵢ(0≦i≦N−1) to UNIQUE (UNIQUE means that an input i is not compatible or inversely compatible);
detecting compatibility between an input v(i,k) and a comparison input v(j,k) over the entire test sequence k(0≦k≦L−1) of the given test data T_{D} using a function is compatible; and
confirming whether there are values that conflict with previous other compatible inputs or inversely compatible inputs using a function conflict check within the function is compatible if the input v(i,k) or v(j,k) has an ‘X’ value (don't care).

3. The test data compression method as claimed in claim 1, wherein the step (c) replaces all the ‘X’ values with ‘0’s such that the patterns have a lot of ‘0’s, the step (d) includes a step of storing the first value and the last value of each test data pattern in which ‘X’ values have been replaced with ‘0’ and previously calculating the length of the pattern and a step of making the last value of each pattern become identical to a value of the next pattern and re-ordering the sequence of the patterns to generate as many instances as possible of the block to be compressed, so that a block having consecutive ‘0’s can frequently appear, and the step (e) selects and compresses one block having the highest frequency of appearance using the compression code generated in the step (b).

4. A test data decompression apparatus including a controller that decompresses test data compressed by the test data compression method as claimed in claim 1, inputs the decompressed test data to a scan chain in the tested device, and controls signals transmitted between an ATE and an FSM, comprising:
an FSM decoder that includes inputs, one of which is a test clock input and the other an input to which the compressed test data is transmitted from a channel of a tester, and outputs, one of which is a data output port through which original data obtained when the compressed data is decompressed is transmitted and the other an output port through which control signals are output; and
a serializer that inputs the decompressed test data to the scan chain in synchronization with an FSM clock of the FSM decoder and a chip test clock.

5. The test data decompression apparatus as claimed in claim 4, wherein the control signals include a signal “parallel load (Par.)”, a signal “serial load (Ser.)” and a signal “Wait”, when the first bit of the compression bit is ‘1’, which represents an uncompressed pattern, the decoder transmits subsequent bits and the control signal “serial load (Ser.)” to the serializer for two clock cycles, and when the first bit of the compression bit is ‘0’, which indicates one compressed block, the decoder delivers P₀ corresponding to bits of the corresponding block and the control signal “parallel load(Par.)” in parallel to the serializer.

6. A test data decompression apparatus including a controller that decompresses test data compressed by the test data compression method as claimed in claim 2, inputs the decompressed test data to a scan chain in the tested device, and controls signals transmitted between an ATE and an FSM, comprising:
an FSM decoder that includes inputs, one of which is a test clock input and the other an input to which the compressed test data is transmitted from a channel of a tester, and outputs, one of which is a data output port through which original data obtained when the compressed data is decompressed is transmitted and the other an output port through which control signals are output; and
a serializer that inputs the decompressed test data to the scan chain in synchronization with an FSM clock of the FSM decoder and a chip test clock.

7. The test data decompression apparatus as claimed in claim 6, wherein the control signals include a signal “parallel load (Par.)”, a signal “serial load (Ser.)” and a signal “Wait”, when the first bit of the compression bit is ‘1’, which represents an uncompressed pattern, the decoder transmits subsequent bits and the control signal “serial load (Ser.)” to the serializer for two clock cycles, and when the first bit of the compression bit is ‘0’, which indicates one compressed block, the decoder delivers P₀ corresponding to bits of the corresponding block and the control signal “parallel load(Par.)” in parallel to the serializer.

8. A test data decompression apparatus including a controller that decompresses test data compressed by the test data compression method as claimed in claim 3, inputs the decompressed test data to a scan chain in the tested device, and controls signals transmitted between an ATE and an FSM, comprising:
an FSM decoder that includes inputs, one of which is a test clock input and the other an input to which the compressed test data is transmitted from a channel of a tester, and outputs, one of which is a data output port through which original data obtained when the compressed data is decompressed is transmitted and the other an output port through which control signals are output; and
a serializer that inputs the decompressed test data to the scan chain in synchronization with an FSM clock of the FSM decoder and a chip test clock.

9. The test data decompression apparatus as claimed in claim 8, wherein the control signals include a signal “parallel load (Par.)”, a signal “serial load (Ser.)” and a signal “Wait”, when the first bit of the compression bit is ‘1’, which represents an uncompressed pattern, the decoder transmits subsequent bits and the control signal “serial load (Ser.)” to the serializer for two clock cycles, and when the first bit of the compression bit is ‘0’, which indicates one compressed block, the decoder delivers P₀ corresponding to bits of the corresponding block and the control signal “parallel load(Par.)” in parallel to the serializer.
